(19) United States
(12) Patent Application Publication
(10) Pub. No.: US 2026/0360662 A1
(43) Pub. Date: Nov. 12, 2026

(54) MACHINE LEARNING EMULATION OF PHYSICAL MODEL IN SEMICONDUCTOR EXAMINATION

(71) Applicant: Applied Materials Israel Ltd., Rehovot (IL)

(72) Inventors: Shay ATTAL, Rehovot (IL); Nahum BOMSHTEIN, Modi'in-Maccabim-Re'ut (IL); Tal ITZKOVICH, Tel-Aviv (IL)

(21) Appl. No.: 19/200,557

(22) Filed: May 6, 2025

(51) Int. Cl. H01J 37/22; G06F 30/27; G06T 7/00; H01J 37/28

(52) U.S. Cl. CPC H01J 37/222; G06F 30/27; G06T 7/0004; G06T 2207/10061; G06T 2207/20081; G06T 2207/30148; G06T 2207/30168; H01J 37/28; H01J 2237/221

(57) ABSTRACT

The presently disclosed subject matter relates to a machine learning-based approach for augmenting Scanning Electron Microscope (SEM) imaging in semiconductor examination. A machine learning model is trained on outputs generated by a physical model that simulates electron beam interactions with a semiconductor specimen, using input data comprising SEM parameters. Once trained, the model approximates physical model results significantly faster, enabling real-time prediction of SEM outputs. The disclosed subject matter further includes a computer-implemented method, a system, and a non-transitory computer-readable medium configured to receive input data, execute the trained machine learning model, generate emulated SEM outputs, and adapt SEM parameters accordingly. The adapted parameters are applied during SEM operation, thereby enhancing imaging precision, improving defect detection, and increasing overall semiconductor manufacturing efficiency and quality.

### FIELD OF THE INVENTION

The present invention relates to semiconductor manufacturing and examination.

### BACKGROUND OF THE INVENTION

Scanning Electron Microscopy (SEM) is a versatile device having an important role in semiconductor wafer fabrication, supporting processes such as metrology and defect detection. SEM is often employed as a review tool, providing in-depth examination of defects and measurement accuracy throughout manufacturing stages. Through detailed visualization and measurement capabilities, SEM helps characterize defects, measure critical dimensions, and supports overall process control, thereby enhancing yield and maintaining device functionality.

One challenge in semiconductor imaging is defining the SEM tool recipe used to achieve high-quality imaging. An SEM tool recipe is a predefined set of SEM parameters (also referred to as “SEM settings”), including both operational parameters and control instructions, used to control the SEM during operation. SEM parameters include settings such as acceleration voltage, beam current, magnification, scan speed, detector configuration, and working distance. Control instructions may additionally define basic measurement conditions, such as signal thresholding or edge detection criteria. The selection and application of SEM parameters directly affect image resolution, contrast, and signal clarity. Suboptimal settings may degrade image quality, hindering defect detection and metrology.

To address this, physical models simulate electron beam-specimen interactions using parameters such as stack information (layer composition, thickness, material properties), pattern geometries, and SEM settings. Employing stochastic methods like Monte Carlo simulations, these models predict electron scattering, secondary electron generation, and produce simulated SEM images, signal intensity maps, and scattering profiles.

Analyzing these simulations enables selection of optimal SEM parameters, reducing reliance on costly trial-and-error methods, and enhancing imaging accuracy, defect detection reliability, and overall manufacturing quality.

### GENERAL DESCRIPTION

According to a first aspect of the presently disclosed subject matter, there is provided a computer-implemented method of augmenting examination tool output (e.g., Scanning Electron Microscope (SEM)) imaging output of a semiconductor specimen, the method comprising:
receiving input data corresponding to the semiconductor specimen, the input data including parameters that characterize the specimen and a set of examination tool parameters; applying a machine learning model on the input data, wherein the machine learning model is trained to emulate a physical model that simulates examination tool outputs generated by interactions between an electron beam and the semiconductor specimen, wherein the machine learning model generates the outputs faster than the physical model;
generating, using the machine learning model, outputs that emulate results of the physical model based on the input data;
providing a set of examination tool parameters selected according to the outputs to the examination tool to enable applying the examination tool parameters during examination tool operation and thereby augment examination tool imaging outputs.

In addition to the above features, the method according to this aspect of the presently disclosed subject matter can optionally comprise one or more of features (i) to (ix) below, in any technically possible and technically possible combination or permutation:
i. Wherein the outputs comprise at least one of: simulated examination tool (e.g., SEM) images, signal intensity maps, and electron scattering profile.
ii. wherein the method further comprises executing multiple instances of the machine learning model concurrently, each instance applying a different set of examination tool (e.g., SEM) parameters; generating multiple outputs, each corresponding to a uniquely modified set of examination tool (e.g., SEM) parameters; and selecting a preferred set of examination tool (e.g., SEM) parameters from the multiple outputs based on predefined evaluation criteria.
iii. wherein the method further comprises: iteratively applying the machine learning model on the input data; and for each iteration, generating updated input data that includes a different set of examination tool (e.g., SEM) parameters, applying the machine learning model on the updated input data to obtain respective outputs, analyzing the respective outputs to determine respective output quality, and selecting an optimal set of examination tool (e.g., SEM) parameters according to the respective output quality.
iv. wherein the semiconductor specimen comprises multiple layers, the input data is multi-layer input data that includes parameters corresponding to these multiple layers, and wherein the machine learning model is trained to approximately emulate outputs of a physical model using the multi-layer input data to account for cross-layer variations within the semiconductor specimen.
v. wherein the method further comprises: receiving input data indicative of one or more imaging objectives; for each indicated imaging objective, selecting and executing a corresponding machine learning model from the plurality of machine learning models; generating, by each selected machine learning model, a respective output that emulates results of a physical model for the corresponding imaging objective; and evaluating the generated outputs and adjusting respective examination tool (e.g., SEM) parameters to refine examination tool (e.g., SEM) imaging output for each of the one or more imaging objectives.
vi. wherein the parameters that characterize the specimen comprise stack information and pattern geometries.
vii. wherein the multi-layer input data comprises stack information that includes layer composition, thickness, and material properties of multiple layers of the semiconductor specimen;
viii. wherein generating the outputs using the machine learning model enables real-time adaptation of examination tool (e.g., SEM) parameters.
ix. Wherein the method further comprises applying the selected examination tool (e.g., SEM) parameters during examination tool (e.g., SEM) operation to obtain augmented examination tool (e.g., SEM) output.

According to a second aspect of the presently disclosed subject matter there is provided a computer system comprising a processing circuitry configured to execute the method of the first aspect above.

According to a third aspect of the presently disclosed subject matter there is provided a non-transitory computer-readable medium comprising instructions that, when executed by a computer, cause the computer to perform a method according to the first aspect above.

According to a fourth aspect of the presently disclosed subject matter there is provided a computer program product comprising a non-transitory computer-readable medium having computer-executable instructions stored thereon, which, when executed by a processor, cause the processor to execute a method according to the first aspect above.

According to a fifth aspect of the presently disclosed subject matter there is provided a semiconductor examination tool comprising a processing circuitry configured to execute a method of the first as disclosed herein.

The methods, the systems, the non-transitory program storage devices, and the examination tool disclosed with reference to the second, third, fourth and fifth aspects, can optionally comprise one or more of features (i) to (ix) listed above, mutatis mutandis, in any technically possible combination or permutation.

The presently disclosed subject matter further contemplates:

A computer program product stored on a non-transitory computer-readable medium, comprising instructions which, when executed by a computer, cause the computer to:

execute a machine learning model configured to: receive input data comprising parameters that characterize a semiconductor specimen and a set of SEM parameters; and generate output data that emulates results of a physical model simulating interactions between an electron beam and the semiconductor specimen.

Wherein in some examples the non-transitory computer-readable medium is made available to an examination tool, enabling the examination tool to apply the generated SEM parameters during imaging or measurement operations, thereby augmenting the SEM output.

A computer-implemented method (and a computer system configured to execute the method) of emulating a physical model simulating interactions between an electron beam and a semiconductor specimen, the method comprising:
executing a machine learning model configured to
receive input data comprising parameters that characterize a semiconductor specimen and a set of SEM parameters; and generate output data that emulates results of the physical model based on the input data.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIG. 1A shows a block diagram schematically illustrating a system, in accordance with certain examples of the presently disclosed subject matter;

FIG. 1B shows an example of a combination of modules that can be implemented as part of a processing circuitry of the system illustrated in FIG. 1A, in accordance with certain examples of the presently disclosed subject matter.

FIG. 2 is a flowchart of operations carried out as part of training and execution of a physical model emulation ML model, in accordance with certain examples of the presently disclosed subject matter; and

FIG. 3 is a flowchart of operations carried out during SEM augmentation process, in accordance with certain examples of the presently disclosed subject matter.

### DETAILED DESCRIPTION

SEM imaging involves directing a focused beam of high-energy electrons toward a specimen surface, generating detailed grayscale images by detecting signals produced from electron-sample interactions. As the electron beam scans across the surface of the sample, it interacts with the atoms, leading to various outcomes such as the emission of secondary electrons, backscattered electrons, and characteristic X-rays.

The detection of secondary electrons (which are emitted from the near-surface region) allows for high-resolution imaging of the sample's topography. Backscattered electrons, which are primary electrons that undergo elastic scattering by atomic nuclei, provide information on the composition and contrast based on atomic number differences within the sample.

Detectors designed for specific types of emissions capture the signals resulting from these interactions. This collected data is then processed to produce a grayscale image, where intensity variations correspond to differences in signal strength influenced by topography, material composition, and detector positioning. SEM tools can generate highly detailed grayscale images at magnifications far exceeding those of optical microscopes, providing precise inspection and measurement capabilities in semiconductor wafer manufacturing.

As mentioned above, a physical model is used to simulate the interaction between the electron beam and the specimen in an SEM. This simulation incorporates factors such as material properties, pattern geometries, and SEM machine settings. Applying these models is computationally intensive and time-consuming. In multi-layered semiconductor structures, the interaction between the electron beam and the sample depends on the combined effects of multiple layers, including variations in material composition, thickness, and electron scattering behavior. As the number of layers increases, the computational complexity intensifies, making full-scale simulations highly demanding.

The heavy computational burden limits the use of comprehensive simulations for achieving accurate results. High processing demands make it infeasible to evaluate a wide range of parameter combinations. Consequently, simulations are often restricted to modeling interactions with the top layer, both in real-time applications and large-scale offline analyses. Real-time adaptation of SEM parameters is impractical, and large-scale, high-accuracy simulations remain inefficient, restricting their effectiveness in optimizing examination outputs in semiconductor manufacturing

To overcome these limitations, the presently disclosed subject matter introduces a machine learning model dedicated to emulating the physical model and generating its predictions much faster. By training on a dataset of physical model simulations, the machine learning model learns the complex relationships between SEM parameters, material properties, stack information, and the physical model's outputs, allowing it to approximate results much faster. This approach significantly reduces computational overhead, enabling real-time simulation over multiple layers and allowing SEM parameters to be adapted to relevant material properties and imaging conditions in real-time, improving both efficiency and reliability of examination.

The presently disclosed subject matter further contemplates the integration of this machine learning model into SEM-driven processes executed as part of semiconductor manufacturing workflows, such as defect detection and metrology. By providing rapid approximations of physical model outcomes, it facilitates adaptive SEM parameter tuning, allowing for dynamic adjustments. This helps to improve image quality, analysis precision, and overall efficiency in semiconductor examination and quality control.

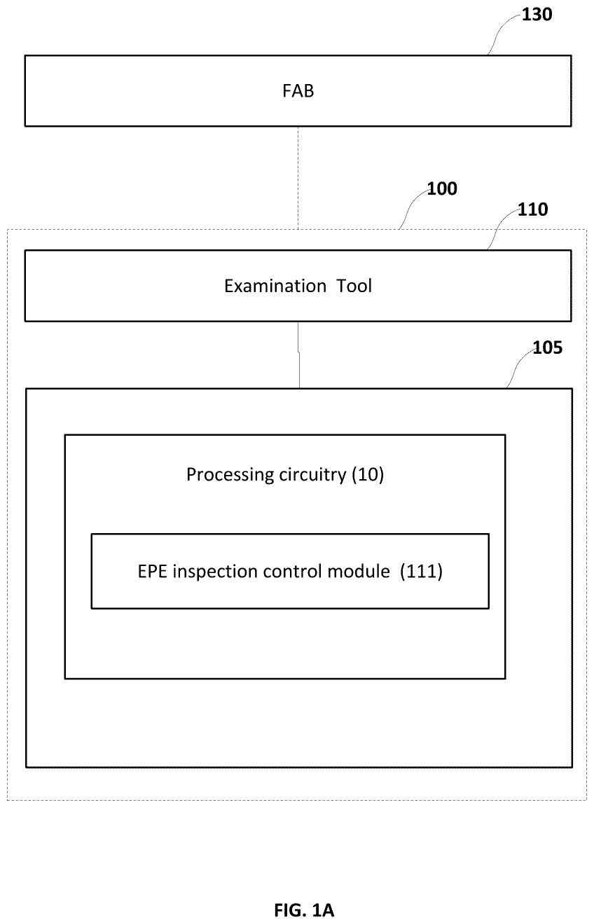

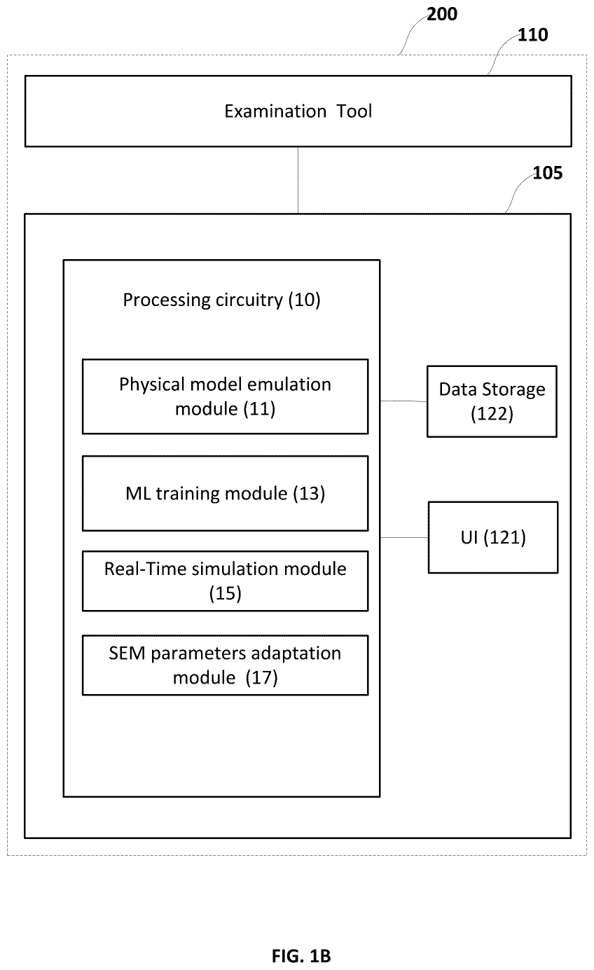

Bearing the above in mind, attention is drawn to FIG. 1A, which is a block diagram illustration of a system 100 configured with physical model emulation technology, according to examples of the presently disclosed subject matter.

FIG. 1A illustrates a schematic representation of a system, which includes an examination tool 110 operatively connected to a semiconductor fabrication facility (FAB 130). Semiconductor specimens, such as wafers generated by the FAB, are analyzed by examination tool 110 that generates images of the specimen to support processes such as defect detection and metrology. In some examples, examination is executed as part of the specimen fabrication process. The term “examination,” as used herein, refers to operations related to the analysis of a semiconductor specimen, including but not limited to defect detection, defect classification, metrology, inspection, and review.

FIG. 1A further illustrates system 100 that comprises the examination tool operatively connected to computer system 105 configured and operable to apply physical model machine learning emulation. The connection between computer system 105 and the examination tool can be established in various ways. For instance, system 105 may be a standalone system connected to an examination tool via a direct connection or a network, may be integrated as a module within the examination tool's internal architecture, or may operate as a cloud-based service accessed by the examination tool.

Per the illustrated example, computer system 105 comprises processing circuitry 10 that is configured to execute various processing operations as further described below. Processing circuitry 10 can comprise one or more processors and one or more memories (not shown). In some examples, the processing circuitry is configured to execute several functional modules based on computer-readable instructions stored in a non-transitory computer-readable memory included in the processing circuitry. These functional modules are hereinafter referred to as being comprised in the processing circuitry.

FIG. 1B is a schematic block-diagram of computer system 100 that shows a none-limiting example of a combination of modules implemented within processing circuitry 10. Physical model emulation module 11, when operating, executes and manages the physical model emulation ML model, which generates rapid predictions that closely approximate physical model results. ML model training module 13, when operating, trains the physical model emulation ML model on physical model simulation datasets, enabling it to learn complex relationships between SEM parameters and physical model outputs. Real-time simulation module 15, during operation performs real-time simulations across multiple layers of semiconductor specimens by utilizing the physical model emulation ML model, allowing for rapid evaluation of various parameter combinations. SEM parameter adaptation module 17, when operating, adapts SEM parameters based on physical model emulation ML model outputs, optimizing image quality and analysis precision.

According to some examples, system 100 can comprise or be otherwise operatively connected to a data-storage unit 122 configured to store any data necessary for operating system 100. This includes for example computer software which is loaded during execution of any one of the modules described above, intermediate processing results generated by system 100, training data used during training of the ML model, physical model emulation outputs, etc.

In some examples, system 100 can comprise a user interface 121 to enable user interaction with system 100. The user interface can include a display device, user interaction devices (e.g., computer mouse and keyboard) and a graphical user interface (GUI) configured to enable, inter alia, user-specified inputs related to system 100. For instance, the user may view on the display the processing results or intermediate processing results, such as, outputs of the physical model emulation ML, etc.

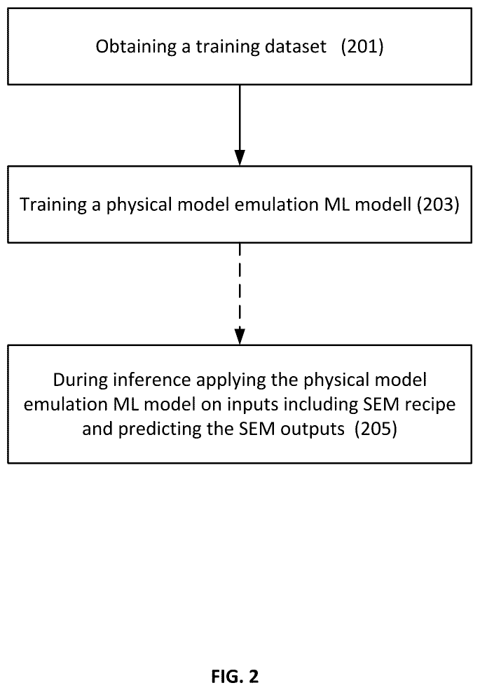

Attention is now drawn to FIG. 2, which illustrates a flowchart of operations carried out during the training of a physical model emulation machine-learning (ML) model, according to some examples of the presently disclosed subject matter.

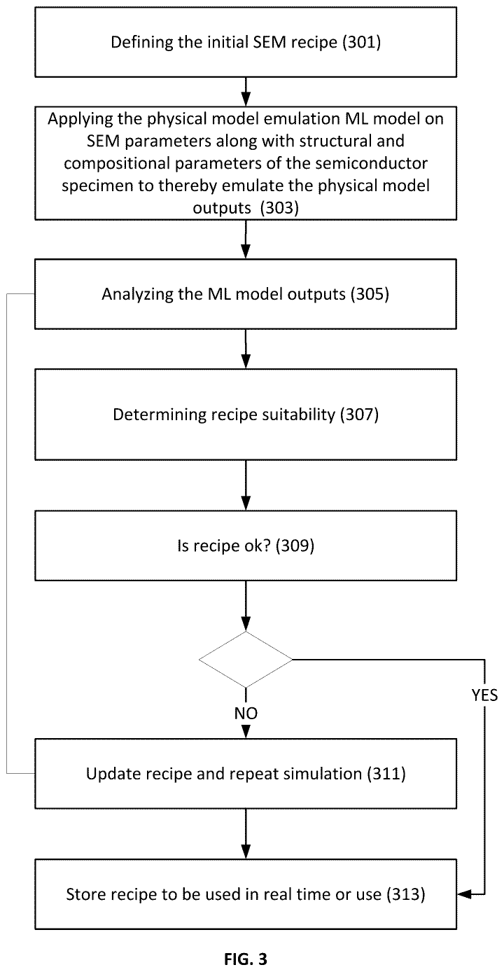

It is noted that while the operations in FIGS. 2 and 3 are described with reference to various components in FIG. 1B, this is provided by way of example only and should not be construed as limiting the processes to the specific system design illustrated in any of these figures.

A training dataset comprising data for training the physical model emulation ML model is obtained (201). The training dataset includes inputs to the physical model, along with their corresponding outputs generated by the physical model that simulates the interaction between the electron beam and the specimen in an SEM. The purpose of this training is to develop a machine learning model that takes the same inputs as the physical model and generates corresponding outputs that reflect the physical model's predictions, but at a significantly higher speed and scale.

To obtain a robust ML model, the training dataset includes information obtained by applying the physical model to a large variety of semiconductor samples. This enables the ML model to learn and generalize across a wide range of semiconductor structures and compositions, enhancing its ability to accurately emulate the physical model's behavior across various scenarios encountered in semiconductor manufacturing.

The inputs to the physical model, which are used in training the ML model, include, for example, key factors such as stack information (layer composition, thickness, and material properties), pattern geometries, and SEM machine settings. These parameters directly influence the interaction between the electron beam and the specimen, affecting image resolution, contrast, and signal clarity. The training enables the physical model emulation ML model to learn the complex relationships between input parameters and the resulting physical model outputs.

The corresponding outputs from the physical model, which serve as the target data for training the ML model, include one or more of: simulated SEM images, signal intensity maps, and electron scattering profiles. These outputs provide detailed information about how the electron beam interacts with the specimen under various conditions.

At block 203, the training dataset is used to train the machine learning model. The model is optimized to generate accurate and rapid approximations of the physical model results under various conditions. Training can be executed, for example, by ML model training module 13. In some examples, the physical model emulation ML model is implemented as a deep neural network (DNN). This DNN can be trained using either a supervised or unsupervised learning approach, with layers organized according to a specific network architecture. The architecture may follow various structures, such as a Convolutional Neural Network (CNN), Recurrent Neural Network (RNN), Recursive Neural Network, Generative Adversarial Network (GAN), or other suitable architectures.

The DNN architecture consists of multiple layers, each containing several neurons or nodes, allowing the physical model emulation ML model to learn complex, non-linear relationships between the input (such as SEM settings, material properties, and pattern geometries) and the corresponding physical model outputs. This enables the model to accurately approximate the behavior of the physical model across a wide range of scenarios, while significantly reducing computation time.

Block 205 refers to the inference stage, where the trained physical model emulation ML model generates rapid predictions. The model is provided with new input data corresponding to specific material properties, pattern geometries, and SEM settings. Given these inputs, the model produces outputs that closely approximate what the physical model would generate under similar conditions but in a fraction of the time.

During inference, the model can be applied using multiple input combinations, enabling fast predictions of SEM outputs. By executing the model across various input configurations, it is possible to rapidly generate a large number of predictions and systematically compare them to benchmark values to identify the optimal SEM settings. This approach accelerates the calibration process, ensuring that imaging and measurement results are optimized efficiently. The ability to quickly explore different parameter sets allows for real-time simulations and adaptive parameter tuning, enhancing both efficiency and reliability in semiconductor manufacturing workflows.

As the physical model emulation ML model can process information more quickly and with considerably reduced computational load, it can incorporate data from multiple layers and account for cross-layer variations. To this end, the training data includes information from multiple layers, allowing the ML model to learn the connection between variations in different layers and the physical model outputs. This includes, for example, stack information that includes structural (e.g., thickness) and material properties of multiple layers and respective. During inference, the ML model is fed with input pertaining to multiple layers (herein below “multi-layer input”), enabling it to produce more accurate predictions by accounting for cross-layer interactions.

Additionally, the accuracy of the model output depends on the specific imaging goal. Imaging objectives include, for example surface resolution, material contrast, or depth penetration. To address this, in some examples, the ML model is trained separately for each imaging objective, utilizing training data comprising physical model inputs, such as SEM recipes, and respective physical model outputs generated under various SEM settings specific to each imaging goal. This targeted training approach improves model accuracy by optimizing separate ML models for different objectives and enabling the determination of objective-specific recipes.

The training dataset includes goal-specific physical model outputs that simulate different SEM imaging objectives. These outputs include for example, high-resolution surface images for surface resolution optimization, material contrast variations for composition analysis, and depth penetration profiles for subsurface feature visibility. In some examples, the training data can further include an indication of the respective imaging objective, allowing the model to learn the relationship between the objective, the SEM parameters, and the corresponding physical model outputs.

To further refine SEM parameters selection, the ML model is trained with predefined SEM parameter ranges tailored to each imaging goal. For instance, high beam voltage settings may be emphasized for depth penetration, while low voltage and short working distance configurations are used for surface resolution. Similarly, contrast-enhancing detector settings are emphasized for material analysis.

During inference, one or more imaging objectives can be selected by an operator, and in response, the relevant trained ML model or models are selected and executed to generate the corresponding SEM output predictions. Unlike conventional physical models, the ML model enables fast SEM output simulation, allowing for the rapid evaluation of multiple configurations. Because the ML model can process different parameter variations efficiently, this approach allows the user to select one or more imaging objectives and refine SEM recipes for all selected objectives in a short time.

According to some examples, system 105 can execute multiple threads (e.g., executed and managed for example by real-time simulation Module 15), each running on a different processor, such as those included in processing circuitry 10. Each thread executes an instance of the physical model emulation ML model, applying a different of input. For example, each thread can apply the ML model on a different recipe. This parallelized execution allows multiple inputs to be evaluated simultaneously, significantly accelerating the optimization process. By distributing computations across multiple processing units, the system efficiently explores the parameter space, identifying optimal SEM settings more rapidly than a single-threaded approach. This capability further enhances real-time SEM calibration and enables adaptive tuning of SEM recipes to accommodate variations in semiconductor structures and material properties.

Proceeding to FIG. 3, which illustrates a flowchart of operations carried out during an SEM augmentation process, according to some examples of the presently disclosed subject matter.

The following process demonstrates the utilization of a machine learning (ML) model for physical model emulation in place of a physical model to improve or optimize SEM operation. By replacing computationally intensive physical model simulations with a trained ML-based physical model emulation, parameter tuning can be significantly accelerated, allowing a greater variety of possible recipes to be evaluated in a short time, enabling selection of better SEM parameters, enhancing imaging precision and improving semiconductor examination efficiency. Operations described with reference to FIG. 3 can be executed, for example, by real-time simulation module 15 which manages the process and interacts with physical model emulation model 11 for utilizing the ML model.

The following process utilizes a physical model emulation ML model in the process of defining a recipe. Given a semiconductor specimen that needs to be examined by the SEM, the recipe parameters are fine-tuned to optimize examination outputs. At block 301, an initial SEM recipe is defined. This initial recipe may be an existing known configuration, or an estimated configuration based on prior imaging data, heuristics, or optimization algorithms. As mentioned above, the recipe includes SEM parameters related to beam settings such as acceleration voltage, beam current, and working distance, scan parameters such as scan rate, dwell time, and magnification, detector settings including secondary and backscattered electron modes and signal amplification, and imaging conditions such as focus, contrast, brightness, and noise filtering. The recipe also defines measurement algorithms used for feature detection, pattern recognition, and threshold settings. These parameters determine the quality of SEM imaging and measurement accuracy, but their optimal values may vary across different types of semiconductor specimens, each having different characteristics, such as different designs and material compositions.

At block 303, the SEM parameters of the SEM recipe along with structural and compositional parameters of the semiconductor specimen, are applied to the physical model emulation ML model to approximate the physical model outputs instead of using a physical model.

At block 305, the simulated SEM outputs are analyzed. The analysis determines how well the selected recipe parameters optimize imaging metrics including for example, imaging contrast, signal-to-noise ratio, resolution fidelity, feature detectability, and measurement accuracy. The evaluation assesses the quality of the simulated SEM output.

At block 307, it is determined whether the SEM recipe meets optimization criteria based on the image quality metrics. If the ML generated results indicate that the imaging and measurement performance is satisfactory across the different layers, the recipe is finalized for use in SEM operation. If inconsistencies are identified—such as reduced contrast in specific layers, signal degradation, or inaccurate feature measurements—further refinement is required, and the process proceeds to block 311.

At block 311, the SEM recipe is refined by adjusting variable SEM parameters in the recipe while keeping layer-specific constants unchanged. The refinement process involves for example, iteratively modifying parameters such as beam settings, detector configurations, scan parameters, and measurement algorithms.

The updated SEM recipe is then re-applied to the physical model emulation ML model, and the simulation-execution-evaluation cycle repeats to assess the impact of the adjustments. This cycle is repeated until satisfactory results are obtained from the ML model.

According to other examples, rather than evaluating each ML output individually before deciding whether to execute another iteration, multiple runs are executed in parallel or sequentially, each with different parameter adjustments. These adjustments can follow, for example, predefined heuristics or logic-based variations, allowing a broad range of parameter configurations to be explored in a single execution cycle. In another example, these two approaches can be combined, where multiple runs are executed in parallel, and in each run, multiple different parameter adjustments are applied in parallel. If the outcomes of these parallel adjustments within a run are insufficient to meet the desired criteria, additional runs can be executed, each again involving multiple new parameter adjustments in parallel, thereby progressively expanding the exploration space until satisfactory results are achieved.

As mentioned above, this can involve the execution of the ML model on multiple processes concurrently, such as by utilizing multi-threading, parallel computing, or distributed processing. Each process applies different SEM parameter variations, enabling efficient exploration of a large configuration space. By leveraging techniques such as multi-core processors or GPU acceleration, the system can execute numerous ML model evaluations simultaneously, significantly reducing computational time. This batch simulation approach is made possible by the fast-processing capabilities of the ML-based physical model emulation, which generates results significantly faster than traditional computationally intensive physical models.

At the end of the process the optimal SEM recipe is selected based on predefined evaluation criteria, such as image clarity, resolution, or signal-to-noise ratio. This approach eliminates the need for incremental decision-making after each run, accelerating the optimization process.

At block 313, once an optimized SEM recipe is determined, it is stored and provided for real-time SEM operation. The optimized recipe is applied to the SEM system to ensure consistent imaging and measurement accuracy across different layers, improving defect detection, metrology precision, and overall semiconductor manufacturing quality.

The term “examination tool” as used herein should be broadly interpreted to cover various tools used in examination-related processes of a semiconductor specimen. Examination tools include, for example, various focused charged particle beam devices (FCPB) that can be used in examination-related processes. FCPB tools include, for example, Scanning Electron Microscopes (SEM), Transmission Electron Microscopes (TEM), Focused Ion Beam (FIB) systems, and Scanning Transmission Electron Microscopes (sTEM). Additionally, examination tools encompass optical devices, such as optical microscopes, which are used for imaging, and tools like ellipsometers and reflectometers, which are used to measure film thickness and optical properties such as refractive index and reflectivity in semiconductor specimens. Images generated by an examination tool are also referred to herein as “examination output images”.

The term “emulation,” as used herein, refers to modeling, replicating, or otherwise approximating the behavior, functionality, or characteristics of a system, method, process, or phenomenon. The term is not limited to exact or identical imitation and encompasses variations, adaptations, or deviations that sufficiently represent the system, method, process, or phenomenon being emulated, as would be recognized by a person skilled in the art.

Those versed in the art will readily appreciate that the teachings of the presently disclosed subject matter are not bound by the system illustrated in FIGS. 1A and 1B. Each system component and module in FIGS. 1A and 1B can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified, and/or different components, modules, and functions than those shown in FIGS. 1A and 1B.

Each component in FIGS. 1A and 1B may represent one or more instances of the same component. These instances may operate independently or cooperatively to process various data and electrical inputs and enable operations associated with a computerized examination system. Multiple instances of a component may be employed for purposes such as improving performance, ensuring redundancy, enhancing availability, or supporting specific functionality. For example, certain portions of a component's functionality may be allocated across different instances of the component.

While certain examples of the present disclosure refer to a processing circuitry being configured to perform the above-recited operations, the functionalities/operations of the functional modules can be performed by the one or more processors in the processing circuitry in various ways. By way of example, the operations of each module can be performed by a specific processor, or by a combination of processors. The operations of the various functional modules, such as processing the examination/inspection image, and performing defect examination, etc., can thus be performed by respective processors (or processor combinations), while, optionally, these operations may be performed by the same processor. The present disclosure should not be limited to being construed as one single processor always performing all the operations. The present disclosure should not be construed as limiting the described operations to being performed exclusively by a single processing circuitry. Furthermore, any reference made in the specification and claims to a single processing circuitry should be interpreted to optionally include multiple processing circuitries. These multiple processing circuitries may operate independently or collaboratively, with interoperability enabling communication, data exchange, and task sharing to achieve the described functionalities.

The systems illustrated in FIGS. 1A and 1B can be implemented in a distributed computing environment, in which one or more of the aforementioned components and functional modules shown in FIGS. 1A and 1B can be distributed over several local and/or remote devices. By way of example, training module 13 can be located at the same entity (in some cases hosted by the same device) or on a different device located at a different location.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

Unless specifically stated otherwise, as apparent from the above discussions, it is appreciated that, throughout the specification, discussions utilizing terms such as “receiving”, “applying”, “generating”, “executing”, or the like, include an action and/or processes of a computer that manipulate and/or transform data into other data, said data represented as physical quantities, e.g. such as electronic quantities, and/or said data representing the physical objects.

The terms “computer” , “computer system”, “computer device”, “computerized device”, “computerized system” or the like used herein, should be expansively construed to include any kind of hardware-based electronic device with one or more data processing circuitries. Each processing circuitry can comprise, for example, one or more processors operatively connected to computer memory, capable of executing stored instructions to perform the operations described herein. Any reference made in the description or claims to a processing circuitry should be construed to include also multiple processing circuitries.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application-specific integrated circuit (ASIC), a field programmable gate array (FPGA), a digital signal processor (DSP), a graphics processing unit (GPU), a network processor, or the like.

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately, or in any suitable sub-combination.

It will also be understood that the system according to the presently disclosed subject matter may be a suitably programmed computer. Likewise, the presently disclosed subject matter contemplates a computer program being readable by a computer for executing the method of the presently disclosed subject matter. The presently disclosed subject matter further contemplates a machine-readable (e.g., non-transitory) memory tangibly embodying a program of instructions executable by the machine for executing the method of the presently disclosed subject matter.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

1. A computer-implemented method of augmenting Scanning Electron Microscope (SEM) imaging output of a semiconductor specimen, the method comprising:
receiving input data corresponding to the semiconductor specimen, the input data including parameters that characterize the specimen and a set of SEM parameters;
applying a machine learning model on the input data, wherein the machine learning model is trained to emulate a physical model that simulates SEM outputs generated by interactions between an electron beam and the semiconductor specimen, wherein the machine learning model generates the outputs faster than the physical model;
generating, using the machine learning model, outputs that emulate results of the physical model based on the input data;
providing a set of SEM parameters selected according to the outputs to the SEM to enable applying the SEM parameters during SEM operation and thereby augmenting SEM imaging outputs.

2. The method of claim 1, further comprising:
executing multiple instances of the machine learning model concurrently, each instance applying a different set of SEM parameters;
generating multiple outputs, each corresponding to a uniquely modified set of SEM parameters; and
selecting a preferred set of SEM parameters from the multiple outputs based on predefined evaluation criteria.

3. The method of claim 1, further comprising:
iteratively applying the machine learning model on the input data; and
for each iteration:
generating updated input data that includes a different set of SEM parameters;
applying the machine learning model on the updated input data to obtain respective outputs;
analyzing the respective outputs to determine respective output quality; and
selecting an optimal set of SEM parameters according to the respective output quality.

4. The method of claim 1, wherein the semiconductor specimen comprises multiple layers, the input data is multi-layer input data that includes parameters corresponding to these multiple layers, and wherein the machine learning model is trained to approximately emulate outputs of a physical model using the multi-layer input data to account for cross-layer variations within the semiconductor specimen.

5. The method of claim 1, wherein the machine learning model comprises a plurality of machine learning models, each trained for a respective imaging objective, the method further comprising:
receiving input data indicative of one or more imaging objectives;
for each indicated imaging objective, selecting and executing a corresponding machine learning model from the plurality of machine learning models;
generating, by each selected machine learning model, a respective output that emulates results of a physical model for the corresponding imaging objective; and
evaluating the generated outputs and adjusting respective SEM parameters to refine SEM imaging output for each of the one or more imaging objectives.

6. The method of claim 1, wherein the parameters that characterize the specimen comprise stack information and pattern geometries.

7. The method of claim 4, wherein the multi-layer input data comprises stack information that includes layer composition, thickness, and material properties of multiple layers of the semiconductor specimen.

8. The method of claim 1, wherein generating the outputs using the machine learning model enables real-time adaptation of SEM parameters.

9. The method of claim 1 further comprising applying the selected SEM parameters during SEM operation.

10. A system comprising at least one processing circuitry configured to:
receive input data corresponding to a semiconductor specimen, the input data including parameters that characterize the specimen and a set of SEM parameters;
apply a machine learning model on the input data, wherein the machine learning model is trained to emulate a physical model that simulates SEM outputs generated by interactions between an electron beam and the semiconductor specimen, and wherein the machine learning model generates outputs faster than the physical model;
generate, using the machine learning model, outputs that emulate results of the physical model based on the input data; and
provide a set of SEM parameters selected according to the outputs to the SEM to enable applying the SEM parameters during SEM operation and thereby augment SEM imaging outputs.

11. The system of claim 10, wherein the processing circuitry is further configured to:
execute multiple instances of the machine learning model concurrently, each instance applying a different set of SEM parameters;
generate multiple outputs, each corresponding to a uniquely modified set of SEM parameters; and
select a preferred set of SEM parameters from the multiple outputs based on predefined evaluation criteria.

12. The system of claim 10, wherein the processing circuitry is further configured to:
iteratively apply the machine learning model on the input data; and for each iteration:
generate updated input data that includes a different set of SEM parameters;
apply the machine learning model on the updated input data to obtain respective outputs;
analyze the respective outputs to determine respective output quality; and
select an optimal set of SEM parameters according to the respective output quality.

13. The system of claim 10, wherein the semiconductor specimen comprises multiple layers, wherein the input data is multi-layer input data that includes parameters corresponding to these multiple layers, and wherein the machine learning model is trained to approximately emulate outputs of a physical model using the multi-layer input data to account for cross-layer variations within the semiconductor specimen.

14. The system of claim 10, wherein the machine learning model comprises a plurality of machine learning models, each trained for a respective imaging objective, and wherein the processing circuitry is further configured to:
receive input data indicative of one or more imaging objectives;
for each indicated imaging objective, select and execute a corresponding machine learning model from the plurality of machine learning models;
generate, by each selected machine learning model, a respective output that emulates results of a physical model for the corresponding imaging objective;
and
evaluate the generated outputs and adjust respective SEM parameters to refine SEM imaging output for each of the one or more imaging objectives.

15. The system of claim 10, wherein the parameters that characterize the specimen comprise stack information and pattern geometries.

16. The system of claim 13, wherein the multi-layer input data comprises stack information that includes layer composition, thickness, and material properties of multiple layers of the semiconductor specimen.

17. The system of claim 10, wherein generating the outputs using the machine learning model enables real-time adaptation of SEM parameters.

18. The system of claim 10, further comprising the SEM, wherein the processing circuitry is configured to provide the selected SEM parameters to the SEM to enable application of the SEM parameters during SEM operation.

19. A non-transitory computer-readable medium having stored thereon instructions that, when executed by processing circuitry, cause the processing circuitry to:
receive input data corresponding to a semiconductor specimen, the input data including parameters that characterize the specimen and a set of examination tool parameters;
apply a machine learning model on the input data, wherein the machine learning model is trained to emulate a physical model that simulates examination tool outputs generated by interactions between an electron beam and the semiconductor specimen, and wherein the machine learning model generates outputs faster than the physical model;
generate, using the machine learning model, outputs that emulate results of the physical model based on the input data; and
providing a set of examination tool parameters selected according to the outputs to the examination tool to enable applying the examination tool parameters during examination tool operation and thereby augmenting examination tool imaging outputs.
